(19) United States
(12) Patent Application Publication
(10) Pub. No.: US 2023/0050236 A1
(43) Pub. Date: Feb. 16, 2023

(54) ANTI-ICING MATERIAL WITH STEALTH FUNCTION, PREPARATION METHOD AND USE THEREOF

(71) Applicant: BEIHANG UNIVERSITY, Beijing (CN)

(72) Inventors: Huawei CHEN, Beijing (CN); Xiaolin LIU, Beijing (CN); Jichen CHEN, Beijing (CN); Yantong ZHU, Beijing (CN); Zehui ZHAO, Beijing (CN); Zelinlan WANG, Beijing (CN); Xiaoyang ZHAN, Beijing (CN); Zheng MA, Beijing (CN)

(21) Appl. No.: 17/695,928

(22) Filed: Mar. 16, 2022

(30) Foreign Application Priority Data
Aug. 10, 2021 (CN) 202110913572.9

(51) Int. Cl. B64D 15/12; H05B 3/22; C23C 14/35; C23C 14/20; C23C 14/04; C09D 5/00; C09D 7/40; C09D 7/61; C09D 183/04; C09D 175/04; C09D 109/06

(52) U.S. Cl. CPC B64D 15/12; H05B 3/22; C23C 14/35; C23C 14/205; C23C 14/042; C09D 5/00; C09D 7/70; C09D 7/61; C09D 183/04; C09D 175/04; C09D 109/06

(57) ABSTRACT

Disclosed are an anti-icing material with stealth function, a preparation method and use thereof. The anti-icing material with stealth function according to the disclosure includes an electrically insulating and thermally insulating layer, a patterned heating layer, an electrically insulating and thermally conducting layer, and a hydrophobic layer, that are disposed sequentially through stacking, wherein the patterned heating layer has a patterned hollowed-out structure.

### CROSS REFERENCE TO RELATED APPLICATION

This application claims the benefit and priority of Chinese Patent Application No. 202110913572.9 filed on Aug. 10, 2021, the disclosure of which is incorporated by reference herein in its entirety as part of the present application.

### TECHNICAL FIELD

The present disclosure belongs to the technical field of functional materials, and particularly relates to an anti-icing material with stealth function, a preparation method and use thereof.

### BACKGROUND ART

Aircraft icing refers to the phenomenon that when an aircraft is flying in the atmosphere, an ice layer accumulates on the surface of the parts thereof. Aircraft icing may occur in parts such as aerofoil, tail wing, air inlet leading edge of the engine, windshield and instrument sensor, which is an important cause of flight accidents. Anti-icing ability of an aircraft has become an important index to assess the all-weather flight performance of the aircraft. Stealth flight vehicle (stealth aircraft) requires extremely low radar cross section (RCS), and the surface thereof is required to be wave-absorbing materials or structures with low conductivity, high dielectric loss or high magnetic loss. Also, stealth flight vehicle has an urgent need for anti-icing of fuselage.

However, as for conventional anti-icing materials, a hot-air anti-icing method requires a temperature as high as 200-300° C. Neither the wave-absorbing coating nor absorber structure, however, could withstand the high temperature of 200-300° C. An electrical heating method involves a metal wire heating film, which strongly reflects electromagnetic wave, thus greatly and adversely affecting the stealth effect. It is impossible to achieve a complete anti-icing effect under flight conditions by passive superhydrophobic anti-icing methods alone. Therefore, there is no anti-icing technology compatible with stealth technology at present, which limits the all-weather safe flight capability of a stealth aircraft.

### SUMMARY

In view of the above, an object of the present disclosure is to provide an anti-icing material with stealth function, and the anti-icing material with stealth function according to the present disclosure have advantages of low radar cross section and excellent anti-icing performance.

To realize the above object, the present disclosure provides the following technical solutions:

The present disclosure provides an anti-icing material with stealth function, comprising an electrically insulating and thermally insulating layer, a patterned heating layer, an electrically insulating and thermally conducting layer, and a hydrophobic layer that are disposed sequentially through stacking, wherein the patterned heating layer has a patterned hollowed-out structure, and the patterned heating layer has a thickness of 20-400 μm.

In some embodiments, the electrically insulating and thermally insulating layer is made of a material comprising at least one selected from the group consisting of polyimide, glass fiber, hollow glassy microspheres, silicone rubber, and polyurethane, and the electrically insulating and thermally insulating layer has a thickness of 10-20 μm.

In some embodiments, the patterned heating layer comprises a polymer and a nano electrically conductive filler dispersed in the polymer, wherein a mass ratio of the polymer to the nano electrically conductive filler is in a range of (4-6):(1-2).

In some embodiments, the polymer comprises at least one selected from the group consisting of silicone rubber, epoxy resin, styrene-butadiene-styrene block copolymer, styrene butadiene rubber and polyurethane, and the nano electrically conductive filler comprises at least one selected from the group consisting of graphene, electrically conductive carbon black, carbon nanotubes, nano graphite powder, a nano metal powder, and a nano metal wire.

In some embodiments, the patterned hollowed-out structure of the patterned heating layer has a pattern that is at least one selected from the group consisting of a transversely and longitudinally symmetrical connectivity pattern, a pattern formed by removing a transversely and longitudinally symmetrical connectivity pattern from a bulk film, and a pattern formed by subjecting a transversely and longitudinally symmetrical connectivity pattern to a fractal processing;

wherein the pattern of the patterned hollowed-out structure is constructed of several pattern units, and the pattern units have a size of not larger than 100 mm.

In some embodiments, the patterned hollowed-out structure of the patterned heating layer is a one-layer structure or multiple-layer structure,

wherein, under the condition that the patterned hollowed-out structure is a multiple-layer structure, no additional material, a wave-absorbing material or a wave-transmitting material is added between layers of the patterned hollowed-out structure.

In some embodiments, the patterned heating layer further comprises an electrode connected with the patterned heating layer at each end thereof.

In some embodiments, the electrically insulating and thermally conducting layer comprises a polymer matrix and a substance with high thermal conductivity and low electrical conductivity dispersed in the polymer matrix,

wherein the substance with high thermal conductivity and low electrical conductivity comprises at least one selected from the group consisting of a nitride with high thermal conductivity and low electrical conductivity, an oxide with high thermal conductivity and low electrical conductivity, and a thermally conductive silicone grease,

the polymer matrix comprises at least one selected from the group consisting of silicone rubber, epoxy resin, styrene-butadiene-styrene block copolymer, and polyurethane, and

the electrically insulating and thermally conducting layer has a thickness of not larger than 100 μm.

The present disclosure further provides a method for preparing the anti-icing material with stealth function described in the above technical solutions, comprising

providing the electrically insulating and thermally insulating layer;

preparing the patterned heating layer on a surface of the electrically insulating and thermally insulating layer,

preparing the electrically insulating and thermally conducting layer on a surface of the patterned heating layer, and

preparing the hydrophobic layer on a surface of the electrically insulating and thermally conducting layer to obtain the anti-icing material with stealth function.

The present disclosure further provides use of the anti-icing material with stealth function described in the above technical solutions or the anti-icing material with stealth function prepared by the method described in the above technical solutions as a surface material of equipment.

The present disclosure provides an anti-icing material with stealth function, comprising an electrically insulating and thermally insulating layer, a patterned heating layer, an electrically insulating and thermally conducting layer, and a hydrophobic layer that are disposed sequentially through stacking, wherein the patterned heating layer has a patterned hollowed-out structure, and the patterned heating layer has a thickness of 20-400 μm. In the present disclosure, the electrically insulating and thermally insulating layer is beneficial to avoiding the loss of heat and improving the effect of heat on anti-icing. The patterned heating layer is beneficial to making a part of electromagnetic waves be absorbed by the anti-incing material with stealth function through generating an eddy current and resonance in the patterned hollowed-out structure, and making a part of electromagnetic waves freely diffract, thus obtaining a better transmission effect, and further contributing to reducing the radar cross section of the anti-icing material with stealth function. Moreover, when being electrified, the patterned heating layer could uniformly generate heat, which is beneficial to achieving electric heating anti-icing and de-icing effect simultaneously with stealth effect. The electrically insulating and thermally conducting layer is beneficial to transferring heat to the hydrophobic layer, thus improving electric heating anti-icing and de-icing effect on the basis of the highly hydrophobic performance of the hydrophobic layer. In the present disclosure, the synergistic effect of each layer of the anti-icing material with stealth function is beneficial to making the equivalent impedance wave of the anti-icing material with stealth function almost the same as the impedance wave of air, reducing the reflectivity of electromagnetic waves, and improving the transmissivity of electromagnetic waves, thus realizing electromagnetic wave stealth under the condition of ensuring anti-icing effect.

The results of the tests in examples show that the anti-icing material with stealth function according to the present disclosure has advantages of a simulated result of the electromagnetic wave transmissitivity being basically consistent with the actually measured result, low radar cross section, and excellent anti-icing performance.

### BRIEF DESCRIPTION OF THE DRAWINGS

FIG. 1 is a schematic diagram of the structure of the anti-icing material with stealth function according to some embodiments of the present disclosure, in which 1 represents an electrically insulating and thermally insulating layer, 2 represents a patterned heating layer, 3 represents an electrically insulating and thermally conducting layer, 4 represents a hydrophobic layer, and 5 represents an electrode.

FIG. 2 is a schematic diagram of some pattern units of the patterned heating layer according to some embodiments of the present disclosure.

FIG. 3A shows a pattern obtained by a laser engraving treatment according to Example 1, in which panel shows a pattern of a patterned hollowed-out structure, and panel.

FIG. 3B shows a pattern unit.

FIG. 4 shows a thermal imaging map of the anti-icing material with stealth function as prepared in Example 1.

FIG. 5 shows a simulated test result of the reflectivity of the anti-icing material with stealth function as prepared in Example 1.

FIG. 6 shows an actually measured result of the reflectivity of the anti-icing material with stealth function as prepared in Example 1.

FIG. 7 shows a simulated test result of the transmissivity of the anti-icing material with stealth function as prepared in Example 1.

FIG. 8 shows an actually measured result of the transmissivity of the anti-icing material with stealth function as prepared in Example 1.

FIG. 9 shows an observed surface of the anti-icing material with stealth function as prepared in Example 1 before heating.

FIG. 10 shows an observed surface of the anti-icing material with stealth function as prepared in Example 1 during heating.

FIG. 11 shows a pattern unit of the patterned hollowed-out structure according to Example 2.

FIG. 12 shows a thermal imaging map of the anti-icing material with stealth function as prepared in Example 2.

FIG. 13 shows a simulated test result of the reflectivity of the anti-icing material with stealth function as prepared in Example 2.

FIG. 14 shows an actually measured result of the reflectivity of the anti-icing material with stealth function as prepared in Example 2.

FIG. 15 shows a simulated test result of the transmissivity of the anti-icing material with stealth function as prepared in Example 2.

FIG. 16 shows an actually measured result of the transmissivity of the anti-icing material with stealth function as prepared in Example 2.

FIG. 17 shows an observed surface of the anti-icing material with stealth function as prepared in Example 2 before heating.

FIG. 18 shows an observed surface of the anti-icing material with stealth function as prepared in Example 2 during heating.

### DETAILED DESCRIPTION OF THE EMBODIMENTS

The present disclosure provides an anti-icing material with stealth function, comprising an electrically insulating and thermally insulating layer, a patterned heating layer, an electrically insulating and thermally conducting layer, and a hydrophobic layer that are deposited sequentially through stacking, wherein the patterned heating layer has a patterned hollowed-out structure, and the patterned heating layer has a thickness of 20-400 μm.

In the present disclosure, unless otherwise stated, all components are commercially available products well known to those skilled in the art.

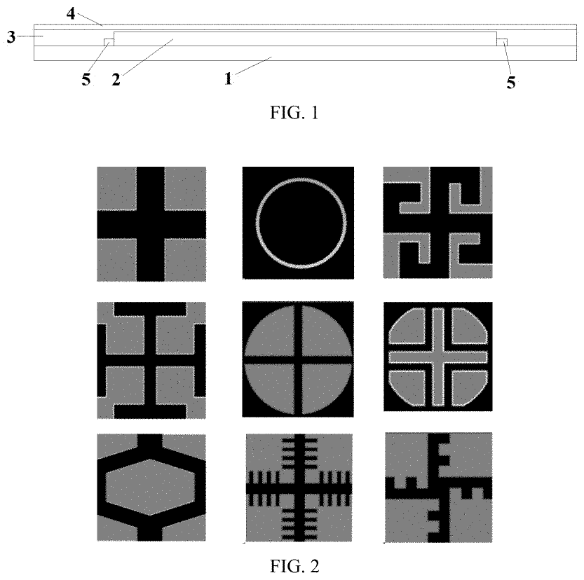

FIG. 1 is a schematic diagram of the structure of the anti-icing material with stealth function according to some embodiments of the present disclosure. The anti-icing material with stealth function will be described below in conjunction with FIG. 1.

In some embodiments of the present disclosure, the anti-icing material with stealth function has a thickness of not larger than 1 mm, and preferably not larger than 0.5 mm.

In the present disclosure, the anti-icing material with stealth function comprises an electrically insulating and thermally insulating layer.

In some embodiments of the present disclosure, the electrically insulating and thermally insulating layer is made of a material comprising at least one selected from the group consisting of polyimide, glass fiber, hollow glassy microspheres, silicone rubber, and polyurethane. In some embodiments, the electrically insulating and thermally insulating layer has a thickness of 10-20 μm, preferably 11-19 μm, and more preferably 12-18 μm.

In the present disclosure, the anti-icing material with stealth function comprises a patterned heating layer arranged on a surface of the electrically insulating and thermally insulating layer.

In some embodiments, the patterned heating layer comprises a polymer and a nano electrically conductive filler dispersed in the polymer. In some embodiments, a mass ratio of the polymer to the nano electrically conductive filler is in a range of (4-6):(1-2), preferably (4.2-5.8):(1.2-1.8), and more preferably (4.4-5.6):(1.3-1.7). In some embodiments, the polymer comprises at least one selected from the group consisting of silicone rubber, epoxy resin, styrene-butadiene-styrene block copolymer, styrene butadiene rubber, and polyurethane. In some embodiments, the nano electrically conductive filler comprises at least one selected from the group consisting of graphene, electrically conductive carbon black, carbon nanotubes, nano graphite powder, a nano metal powder, and a nano metal wire, and preferably electrically conductive carbon black. In some embodiments, the nano metal powder is selected from the group consisting of nano copper powder, nano nickel powder, nano silver powder, and nano aluminum powder. In some embodiments, the nano metal wire is at least one selected from the group consisting of nano copper wire, nano nickel wire, nano silver wire, and nano aluminum wire. In some embodiments, the nano electrically conductive filler has a size of 10-20 μm.

In the present disclosure, the patterned heating layer has a patterned hollowed-out structure. In some embodiments, the patterned hollowed-out structure of the patterned heating layer has a pattern that is at least one selected from the group consisting of a transversely and longitudinally symmetrical connectivity pattern, a pattern formed by removing a transversely and longitudinally symmetrical connectivity pattern from a bulk film, and a pattern formed by subjecting a transversely and longitudinally symmetrical connectivity pattern to a fractal processing. In some embodiments, the pattern of the patterned hollowed-out structure is constructed of several pattern units, and the pattern units have a size of not larger than 100 mm, and preferably not larger than 10 mm. In some embodiments, the pattern units have a pattern comprising at least one selected from the group consisting of a mesh pattern, a Jerusalem cross pattern, a cross pattern combined pattern, a [symbol] pattern, a hollow circular pattern, and a honeycomb pattern. FIG. 2 shows schematic diagrams of some pattern units.

In some embodiments, the patterned hollowed-out structure of the patterned heating layer is a one-layer structure or multiple-layer structure. In some embodiments, under the condition that the patterned hollowed-out structure is a multiple-layer structure, no additional material, a wave-absorbing material or a wave-transmitting material is added between layers of the patterned hollowed-out structure. In some embodiments, the wave-absorbing material comprises at least one selected from the group consisting of an iron-based wave-absorbing material, a carbon-based wave-absorbing material, and an electrically conductive polymer. In some embodiments, the iron-based wave-absorbing material comprises ferric oxide and/or ferrosoferric oxide. In some embodiments, the carbon-based wave-absorbing material comprises at least one selected from the group consisting of graphene, graphite, and silicon carbide.

In some embodiments, the electrically conductive polymer comprises at least one selected from the group consisting of polyaniline/Fe₃O₄ (PANI/Fe₃O₄), a Fe series metal-organic framework (MOF(Fe)), and a carbon nanotube-Fe₃O₄-polyaniline (CNT-Fe₃O₄-PANI). In some embodiments, the wave-transmitting material comprises at least one selected from the group consisting of alumina, silica, glass ceramic, silicon nitride, boron nitride, and a heat-resistant fiber composite. In some embodiments, the heat-resistant fiber composite comprises at least one selected from the group consisting of carbon fiber, boron fiber, aramid fiber, and silicon carbide fiber. In some embodiments, under the condition that the patterned hollowed-out structure is a multiple-layer structure, each layer of the patterned hollowed-out structure has a same or different pattern.

In some embodiments, the patterned heating layer further comprises a regulating element. In some embodiments, the regulating element comprises at least one selected from the group consisting of a resistance, an unilateral diode, and a resistive film. In some embodiments, the regulating element is a patch type regulating element. In some embodiments, the resistance and current direction of the patterned heating layer are regulated by means of the regulating element.

In some embodiments, the patterned heating layer further comprises an electrode connected with the patterned heating layer at each end thereof. In some embodiments, the electrode is a flexible electrode. In some embodiments, the electrode is made of a material comprising at least one selected from the group consisting of an electrically conductive silver adhesive, a carbon fiber, an electrically conductive polymer, and a metal. In some embodiments, the electrode is fixed on the electrically insulating and thermally insulating layer by a means comprising at least one selected from the group consisting of a pasting, a weaving, and a coating. In some embodiments, the coating is performed by scrape coating.

In some embodiments, the patterned heating layer has a thickness of 20-400 μm, preferably 30-390 μm, more preferably 40-380 μm, and further more preferably 50-370 μm.

In the present disclosure, the anti-icing material with stealth function comprises an electrically insulating and thermally conducting layer arranged on a surface of the patterned heating layer.

In some embodiments, the electrically insulating and thermally insulating layer covers the surface of the patterned heating layer, and fills the hollowed-out parts of the patterned hollowed-out structure of the patterned heating layer.

In some embodiments, the electrically insulating and thermally conducting layer comprises a polymer matrix and a substance with high thermal conductivity and low electrical conductivity dispersed in the polymer matrix. In some embodiments, the substance with high thermal conductivity and low electrical conductivity comprises at least one selected from the group consisting of a nitride with high thermal conductivity and low electrical conductivity, an oxide with high thermal conductivity and low electrical conductivity, and a thermally conductive silicone grease. In some embodiments, the nitride with high thermal conductivity and low electrical conductivity comprises at least one selected from the group consisting of aluminium nitride, boron nitride, and silicon nitride. In some embodiments, the oxide with high thermal conductivity and low electrical conductivity comprises at least one selected from the group consisting of alumina, zinc oxide, and silicon oxide.

In some embodiments, the polymer matrix comprises at least one selected from the group consisting of silicone rubber, epoxy resin, styrene-butadiene-styrene block copolymer, and polyurethane. In some embodiments, a mass ratio of the substance with high thermal conductivity and low electrical conductivity to the polymer matrix is in a range of (3-5): 20, preferably (3.2-4.8): 20, and more preferably (3.5-4.5): 20

In some embodiments, the electrically insulating and thermally conducting layer has a thickness of not larger than 100 μm, and preferably not larger than 50 μm.

In the present disclosure, the anti-icing material with stealth function comprises a hydrophobic layer arranged on a surface of the electrically insulating and thermally conducting layer.

In some embodiments, the hydrophobic layer is a hydrophobic coating or a hydrophobic surface obtained by subjecting a surface of the electrically insulating and thermally conducting layer to a laser treatment. In the present disclosure, there is no special limitation on the hydrophobic coating, and any hydrophobic coating well known to those skilled in the art may be used.

The present disclosure further provides a method for preparing the anti-icing material with stealth function described in the above technical solutions, comprising

providing the electrically insulating and thermally insulating layer;

preparing the patterned heating layer on a surface of the electrically insulating and thermally insulating layer,

preparing the electrically insulating and thermally conducting layer on a surface of the patterned heating layer, and

preparing the hydrophobic layer on a surface of the electrically insulating and thermally conducting layer to obtain the anti-icing material with stealth function.

In the present disclosure, the electrically insulating and thermally insulating layer is provided.

In the present disclosure, there is no special limitation on the method for preparing the electrically insulating and thermally insulating layer, as long as the material and thickness of the electrically insulating and thermally insulating could be ensured. In the present disclosure, the electrically insulating and thermally insulating layer is made of the same material as that of the electrically insulating and thermally insulating layer described in the above technical solutions, and will not be repeatedly described here.

In the present disclosure, after obtaining the electrically insulating and thermally insulating layer, the patterned heating layer is prepared on a surface of the electrically insulating and thermally insulating layer.

In the present disclosure, before preparing the patterned heating layer, each end of a surface of the electrically insulating and thermally insulating layer is prepared with an electrode. In some embodiments, the electrode is a flexible electrode. In some embodiments, the electrode is made of a material comprising at least one selected from the group consisting of an electrically conductive silver adhesive, a carbon fiber, an electrically conductive polymer, and a metal. In some embodiments, the electrode is prepared by a method comprising at least one selected from the group consisting of a pasting, a weaving, and a coating. In some embodiments, the coating is performed by scrape coating.

In some embodiments, before preparing the two electrodes by the pasting, the weaving or the coating, the method for preparing the anti-icing material with stealth function further comprises masking non-electrode areas of the surface of the electrically insulating and thermally insulating layer to protect the non-electrode areas from the adhesion of electrode substances. In the present disclosure, there is no special limitation on the masking, and any masking well known to those skilled in the art may be used.

In some embodiments, after preparing the electrode by the pasting, the weaving or the coating to obtain a system containing a primary electrode, the method for preparing the anti-icing material with stealth function further comprises curing the system containing the primary electrode to fix the electrode. In some embodiments, the curing is performed by a heat treatment. In some embodiments, the heat treatment is performed in a drying oven. In some embodiments, under the condition that the electrode is made of an electrically conductive silver adhesive, the heat treatment is performed at a temperature of 150-160° C. for 90 min. In some embodiments, under the condition that the electrode is not made of an electrically conductive silver adhesive, the heat treatment is performed at a temperature of 150-160° C., and preferably 55-95° C.; the heat treatment is performed for 2-4 h, and preferably 2.5-4 h.

In some embodiments, after preparing the two electrodes, the patterned heating layer is prepared on a surface of the electrically insulating and thermally insulating layer, wherein the two electrodes are respectively contacted with two ends of the patterned heating layer.

In some embodiments, the patterned heating layer is prepared by a method comprising

mixing a polymer, a nano electrically conductive filler, and a solvent to obtain a heating layer slurry, and

using the heating layer slurry to prepare the patterned heating layer with a patterned hollowed-out structure on a surface of the electrically insulating and thermally insulating layer.

In some embodiments of the present disclosure, a polymer, a nano electrically conductive filler, and a solvent are mixed to obtain a heating layer slurry.

In the present disclosure, the polymer and nano electrically conductive filler are the same as those in the above technical solutions, and will not be repeatedly described here.

In some embodiments, the solvent includes water, ethanol, toluene, xylene, or acetone. In some embodiments, the heating layer slurry includes 40-60 wt. %, preferably 42-58 wt. %, and more preferably 44-56 wt. % of the polymer; 10-20 wt. %, preferably 12-18 wt. %, and more preferably 13-17 wt. % of the nano electrically conductive filler; and a balance of the solvent.

In some embodiments, the mixing of the polymer, the nano electrically conductive filler and the solvent is performed by an ultrasonic dispersion. In the present disclosure, there is no special limitation on the ultrasonic dispersion, and any ultrasonic dispersion well known to those skilled in the art may be used.

In some embodiments, after obtaining the heating layer slurry, the heating layer slurry is used to prepare the patterned heating layer with a patterned hollowed-out structure on a surface of the electrically insulating and thermally insulating layer.

In some embodiments, using the heating layer slurry to prepare the patterned hollowed-out structure is performed by a process of continuous-layer engraving or a process of one-step molding.

In some embodiments, the process of continuous-layer engraving comprises

covering a surface of the electrically insulating and thermally insulating layer with the heating layer slurry, to obtain a continuous heating layer.

In some embodiments, the covering is performed by casting, scrape coating, spraying or bonding. In some embodiments, before covering, areas that do not need to be covered is masked. In some embodiments, the areas that do not need to be covered comprise the two electrodes. In some embodiments, after covering, a system covered with the heating layer slurry is cured. In the present disclosure, there is no special limitation on the curing, as long as the curing of the heating layer slurry could be ensured.

In some embodiments, after obtaining the continuous heating layer, the continuous heating layer is subjected to an engraving treatment to obtain a patterned heating layer with the patterned hollowed-out structure.

In the present disclosure, there is no special limitation on the engraving treatment, and any engraving treatment well known to those skilled in the art may be used. In some embodiments, the engraving treatment is performed by laser engraving. In the present disclosure, material of the continuous heating layer is selectively removed by the engraving treatment to form a hollowed-out structure.

In some embodiments, the process of one-step molding comprises a 3-dimension printing (3D printing), a template replication, an imprinting, or a screen printing.

In some embodiments, under the condition that the patterned heating layer further includes a regulating element, the regulating element is set by a process comprising connecting the regulating element to the patterned heating layer, and then curing under a pressure. In some embodiments, the pressure is in a range of 30-100 Pa/sq.in, and preferably 35-95 Pa/sq.in; the curing under the pressure is performed for 120-300 min, and preferably 120-250 min. In some embodiments, the curing under the pressure is performed in an autoclave.

In some embodiments, under the condition that using the heating layer slurry to prepare the patterned hollowed-out structure is performed by a process of one-step molding, the process further comprises arranging a dielectric substrate on each surface of the patterned hollowed-out structure. In some embodiments, the dielectric substrate is made of a material comprising at least one selected from the group consisting of epoxy resin, glass, and wood. In some embodiments, the dielectric substrate is suitable for the condition that the anti-icing material with stealth function has no flexibility requirement.

In some embodiments, under the condition that the patterned hollowed-out structure has a multiple-layer structure, the above steps for preparing the pattern heating layer are repeated.

In some embodiments, under the condition that the patterned hollowed-out structure has a multiple-layer structure, a wave-absorbing material or a wave-transmitting material is added between layers of the patterned hollowed-out structure. In some embodiments, under the condition that the wave-absorbing material and/or wave-transmitting material is liquid, the wave-absorbing material and/or wave-transmitting material is cured into a fixed shape by using a mold, and then subjected to a multiple-layer laminating by using an autoclave. In some embodiments, under the condition that the wave-absorbing material and/or wave-transmitting material is solid, the wave-absorbing material and/or wave-transmitting material is cut into a required size, and then subjected to a cure laminating by using an autoclave.

In the present disclosure, after obtaining the patterned heating layer, an electrically insulating and thermally conducting layer is prepared on a surface of the patterned heating layer.

In some embodiments, the electrically insulating and thermally conducting layer is prepared by a method comprising

mixing a substance with high thermal conductivity and low electrical conductivity, a polymer matrix, and a dispersion solvent to obtain an electrically insulating and thermally conducting layer slurry,

coating a surface of the patterned heating layer with the electrically insulating and thermally conducting layer slurry, and

curing the electrically insulating and thermally conducting layer slurry.

In some embodiments, the substance with high thermal conductivity and low electrical conductivity and the polymer matrix are the same as those described in the above technical solutions, and will not be described repeatedly.

In some embodiments, the dispersion solvent is selected from the group consisting of water, ethanol, toluene, xylene, and acetone. In some embodiments, in the electrically insulating and thermally conducting layer slurry, a mass ratio of the substance with high thermal conductivity and low electrical conductivity to the polymer matrix to the dispersion solvent is in a range of (3-5): 20:20, preferably (3.2-4.8): 20:20, and more preferably (3.5-4.5): 20:20.

In some embodiments, there is no special limitation on the coating process with the electrically insulating and thermally conducting slurry, and any coating process well known to those skilled in the art may be used.

In some embodiments, the curing is performed by heat-curing. In some embodiments, the heat-curing is performed at a temperature of 50-100° C., and preferably 55-90° C.; the heat-curing is performed for 2-4 h, and preferably 2-3.5 h.

In the present disclosure, after obtaining the electrically insulating and thermally conducting layer, the hydrophobic layer is prepared on a surface of the electrically insulating and thermally conducting layer to obtain the anti-icing material with stealth function.

In some embodiments, the hydrophobic layer is prepared by a process comprising

directly subjecting a surface of the electrically insulating and thermally conducting layer to a hydrophobic treatment, or

preparing a silicone rubber layer on a surface of the electrically insulating and thermally conducting layer, and then subjecting a surface of the silicone rubber layer to a hydrophobic treatment.

In the present disclosure, there is no special limitation on the process for preparing the silicone rubber layer, and any process for preparing a silicone rubber layer well known to those skilled in the art may be used. For example, a method for preparing the silicone rubber comprises mixing silicone rubber and toluene by an ultrasonic dispersion to obtain a solution of silicone rubber in the toluene, spraying the solution onto a surface of the electrically insulating and thermally conducting layer of an obtained electrically insulating and thermally insulating layer-patterned heating layer-electrically insulating and thermally conducting layer composite, and curing the sprayed solution to form the silicone rubber layer on the electrically insulating and thermally conducting layer. In some embodiments, a mass ratio of the silicone rubber to toluene is in a range of (1-2):(10-15), preferably (1-1.5):(10-13).

In some embodiments, the hydrophobic treatment is performed by coating with a hydrophobic material or by a laser treatment.

In the present disclosure, there is no special limitation on the hydrophobic material, and any hydrophobic material well known to those skilled in the art may be used. In the present disclosure, there is no special limitation on the coating means with the hydrophobic material, and any coating means well known to those skilled in the art may be used.

In the present disclosure, there is no special limitation on the laser treatment, and any laser treatment well known to those skilled in the art may be used.

The present disclosure further provides use of the anti-icing material with stealth function described in the above technical solutions or the anti-icing material with stealth function prepared by the method described in the above technical solutions as a surface material of equipment.

In the present disclosure, there is no special limitation on the equipment, and the anti-icing material with stealth function according to the present disclosure is suitable to any equipment requiring functions of electromagnetic waves stealth and anti-icing.

In some embodiments, the equipment is a stealthy mobile flight vehicle. In some embodiments, the stealthy mobile flight vehicle is a stealthy aircraft.

In some embodiments, the use is achieved by directly covering the equipment with the anti-icing material, or by sequentially preparing the electrically insulating and thermally insulating layer, the patterned heating layer, the electrically insulating and thermally conducting layer, and the hydrophobic layer on a surface of the equipment.

In some embodiments, under the condition that the use is achieved by sequentially preparing the electrically insulating and thermally insulating layer, the patterned heating layer, the electrically insulating and thermally conducting layer, and the hydrophobic layer on a surface of the equipment, the surface of the equipment is subjected to a pre-treatment. In some embodiments, the pre-treatment comprises a polishing. In some embodiments, the polishing is performed by a sanding or an abrasive blasting. In the present disclosure, there is no special limitation on the sanding and abrasive blasting, and any sanding and abrasive blasting well known to those skilled in the art may be used. In some embodiments, the pre-treatment allows for improving the adhesion of the anti-incing material with stealth function with the surface of the equipment.

In the present disclosure, steps for sequentially preparing the electrically insulating and thermally insulating layer, the patterned heating layer, the electrically insulating and thermally conducting layer, and the hydrophobic layer on a surface of the equipment are the same as those described in the method for preparing the anti-icing material with stealth function, and will not be repeatedly described here.

In order to further describe the present disclosure, the anti-icing material with stealth function, a preparation method and use thereof according to the present disclosure will be described in detail with reference to examples below, which should not be understood as limiting the scope of the present disclosure. Obviously, the described examples are only part of the examples of the present disclosure, not all of them. Based on the examples in the present disclosure, all other examples obtained by those of ordinary skill in the art without creative labor shall fall within the scope of the present disclosure.

### Example 1

A silicone rubber, hollow glassy microspheres and toluene were mixed in a mass ratio of 4:1:5, obtaining an electrically insulating and thermally insulating slurry. The electrically insulating and thermally insulating slurry was sprayed onto a surface of an epoxy resin substrate, and dried, obtaining an electrically insulating and thermally insulating layer with a thickness of 50 μm.

Non-electrode areas of the electrically insulating and thermally insulating layer were masked with an adhesive tape. A magnetron sputtering with a target material of copper was performed on electrode areas at both ends of the electrically insulating and thermally insulating layer, and the adhesive tape was then removed, obtaining an electrically insulating and thermally insulating layer with two electrodes.

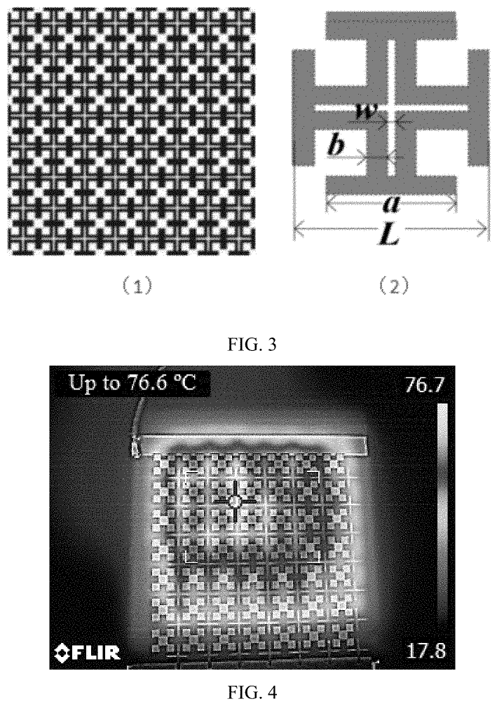

Polyurethane, electrically conductive carbon black and toluene were mixed by an ultrasonic dispersion in a mass ratio of 4:1:5, obtaining a heating layer slurry. Areas in which the preparation of a patterned heating layer was not needed were masked, and the heating layer slurry was sprayed onto a surface of the electrically insulating and thermally insulating layer, and cured, obtaining a continuous heating layer. The continuous heating layer was subjected to a laser engraving treatment, obtaining an electrically insulating and thermally insulating layer-patterned heating layer composite. A pattern obtained by the laser engraving treatment is shown in FIG. 3, in which panel (1) shows a pattern of a patterned hollowed-out structure, panel (2) shows a pattern unit, wherein sizes of the pattern units are respectively as follows: L is 12 mm, a is 8 mm, b is 1.25 mm, w is 0.5 mm, and a thickness h of the pattern unit is 0.05 mm, and the patterned hollowed-out structure of the patterned heating layer is a one-layer structure.

Alumina, polyurethane and toluene were mixed by an ultrasonic dispersion in a mass ratio of 1:4:5, obtaining an electrically insulating and thermally conducting slurry. The electrically insulating and thermally conducting slurry was applied onto a surface of the patterned heating layer, and cured, obtaining an electrically insulating and thermally insulating layer-patterned heating layer-electrically insulating and thermally conducting layer composite.

A silicone rubber and toluene were mixed by an ultrasonic dispersion in a mass ratio of 1:10, obtaining a mixture. The mixture was sprayed onto a surface of the electrically insulating and thermally conducting layer of the electrically insulating and thermally insulating layer-patterned heating layer-electrically insulating and thermally conducting layer composite, and cured, obtaining a silicone rubber layer on the surface of electrically insulating and thermally conducting layer. The silicone rubber layer was subjected to a laser treatment, obtaining a hydrophobic layer on the surface of the silicone rubber layer. The epoxy resin substrate was removed, obtaining the anti-icing material with stealth function with a thickness of 0.5 mm.

Test:

1. Under a given direct current voltage of 110 V and at ambient temperature of 19° C., the anti-icing material with stealth function prepared in Example 1 was observed with a thermal image. The obtained thermal image is shown in FIG. 4. It can be seen from FIG. 4 that the anti-icing material with stealth function according to the present example may be heated to 76° C., indicating that the prepared anti-icing material with stealth function has reliable heating performance.

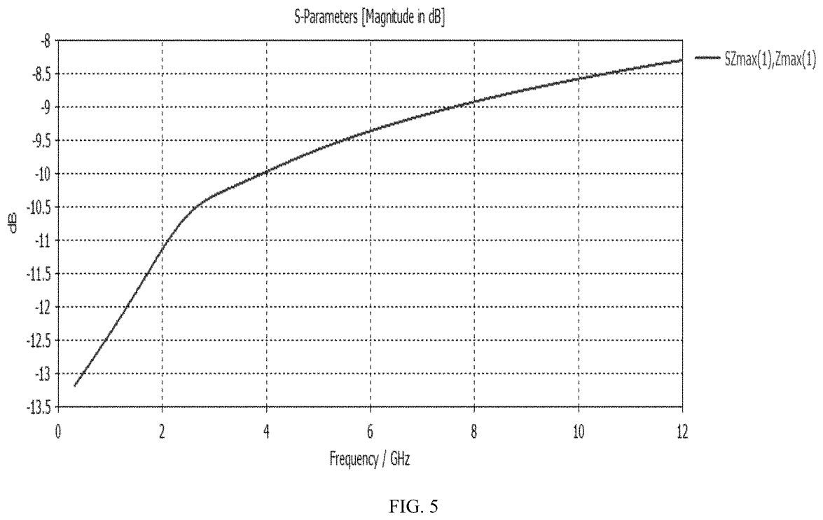

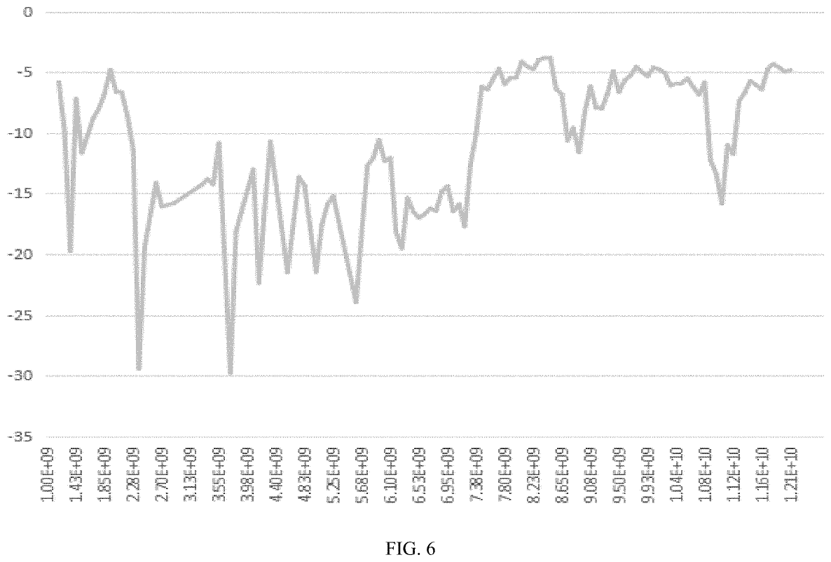

2. The anti-icing material with stealth function prepared in Example 1 was subjected to a reflectivity simulated test and a reflectivity actual test. The test results are shown in FIGS. 5 and 6. FIG. 5 shows the simulated test result of the reflectivity of the anti-icing material with stealth function obtained in Example 1, and FIG. 6 shows the actually measured result of the reflectivity of the anti-icing material with stealth function obtained in Example 1. It can be seen from FIGS. 5 and 6 that in low frequency wave band, the simulated test result of the reflectivity ranges from −13 dB to −10 dB, corresponding to a simulated reflectivity of 5%-10%, and an actually measured result of the reflectivity ranges from −15 dB to −10 dB, corresponding to an actually measured reflectivity of 3%-10%, indicating that the simulated test results are in consistent with the actually measured results.

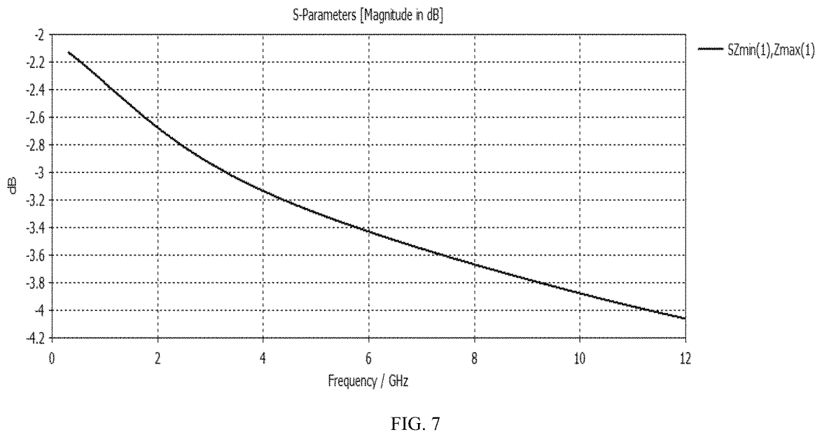

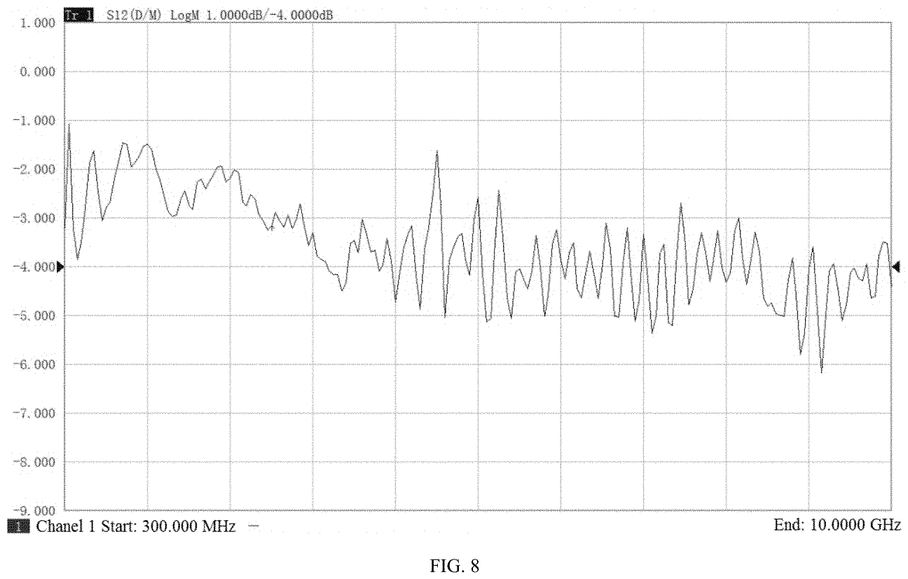

3. The anti-icing material with stealth function prepared in Example 1 was subjected to a transmissivity simulated test and a transmissivity actual test. The test results are shown in FIGS. 7 and 8. FIG. 7 shows the simulated test result of the transmissivity of the anti-icing material with stealth function obtained in Example 1, and FIG. 8 shows the actually measured result of the transmissivity of the anti-icing material with stealth function obtained in Example 1. It can be seen from FIGS. 7 and 8 that a simulated test result of the transmissivity ranges from −4 dB to −2.2 dB, corresponding to a simulated transmissivity of 40%-60%, and an actually measured result of the transmissivity ranges from −3.8 dB to −1.8 dB, corresponding to an actually measured transmissivity of 42%-66%, indicating that the simulated test results are in consistent with the actually measured results.

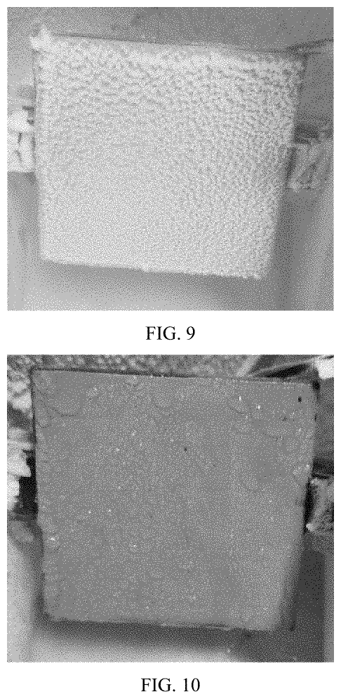

4. Anti-icing test: a sample with a size of 8 cm×8 cm was stood for 3-6 s at ambient temperature of 25° C., a wind tunnel condition (at a temperature of −47° C., a wind velocity of 10 m/s, and a liquid water content of 1.11 g/m³) was simulated, the surface appearances of the sample under non-heating condition and heating condition (at a given power density of 0.325 W/cm²) were respectively observed after being placed in the wind tunnel condition for 1.5 min. The surface appearance of the sample under non-heating condition is shown in FIG. 9, and the surface appearance of the sample under heating condition is shown in FIG. 10. It can be seen from FIGS. 9 and 10 that under the condition that the anti-icing material with stealth function according to the present disclosure is used and electrified, the anti-icing material with stealth function according to the present disclosure could effectively avoid ice attachment.

### Example 2

A silicone rubber, hollow glassy microspheres and toluene were mixed in a mass ratio of 4:1:5, obtaining an electrically insulating and thermally insulating slurry. The electrically insulating and thermally insulating slurry was sprayed onto a surface of an epoxy resin substrate, and dried, obtaining an electrically insulating and thermally insulating layer with a thickness of 100 μm.

Non-electrode areas of the electrically insulating and thermally insulating layer were masked with an adhesive tape. A copper foil was adhered to electrode areas at both ends of the electrically insulating and thermally insulating layer. The adhesive tape was then removed, obtaining an electrically insulating and thermally insulating layer with two electrodes.

Styrene butadiene rubber, nano graphite powder and toluene were mixed by an ultrasonic dispersion in a mass ratio of 4:1:5, obtaining an heating layer slurry. Areas in which the preparation of the patterned heating layer was not needed were masked. The heating layer slurry was sprayed onto a surface of the electrically insulating and thermally insulating layer, and cured, obtaining a continuous heating layer. The continuous heating layer was subjected to a laser engraving treatment, obtaining an electrically insulating and thermally insulating layer-patterned heating layer composite. A pattern unit of a patterned hollowed-out structure obtained by the laser engraving treatment is shown in FIG. 11, wherein sizes of the pattern units are respectively as follows: L is 4 mm, p is 0.9 mm, and a thickness h in the pattern unit is 0.05 mm, and the patterned hollowed-out structure of the patterned heating layer is a one-layer structure.

Silicone oxide, polyurethane and toluene were mixed by an ultrasonic dispersion in a mass ratio of 1:4:5, obtaining an electrically insulating and thermally conducting layer slurry. The electrically insulating and thermally conducting layer slurry was applied onto a surface of the patterned heating layer, and cured, obtaining an electrically insulating and thermally insulating layer-patterned heating layer-electrically insulating and thermally conducting layer composite.

A silicone rubber and toluene were mixed by an ultrasonic dispersion in a mass ratio of 1:10, obtaining a mixture. The mixture was sprayed onto a surface of the electrically insulating and thermally conducting layer of the electrically insulating and thermally insulating layer-patterned heating layer-electrically insulating and thermally conducting layer composite, and cured, obtaining a silicone rubber layer on the surface of electrically insulating and thermally conducting layer. The silicone rubber layer was subjected to a laser treatment, obtaining a hydrophobic layer on the silicone rubber layer. The epoxy resin substrate was removed, obtaining the anti-icing material with stealth function with a thickness of 0.5 mm.

Test

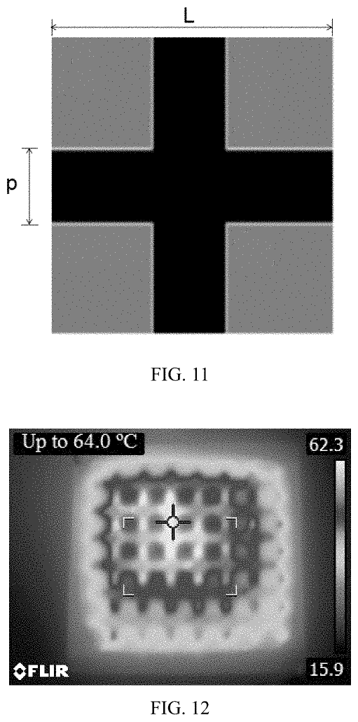

1. Under a given direct current voltage of 110 V and at ambient temperature of 19° C., the anti-icing material with stealth function prepared in Example 2 was observed with a thermal imager. The obtained thermal image is shown in FIG. 12. It can be seen from FIG. 12 that the anti-icing material with stealth function prepared in the present example may be heated to 64° C., indicating that the prepared anti-icing material with stealth function has reliable heating performance.

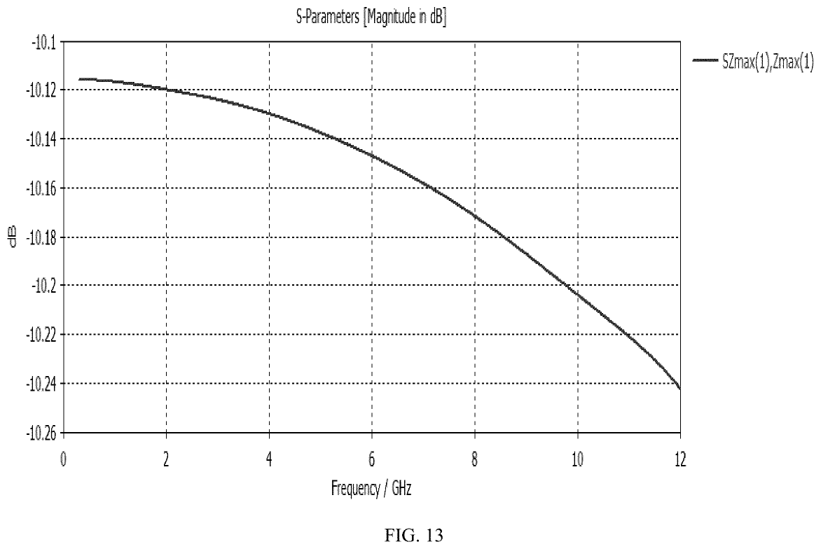

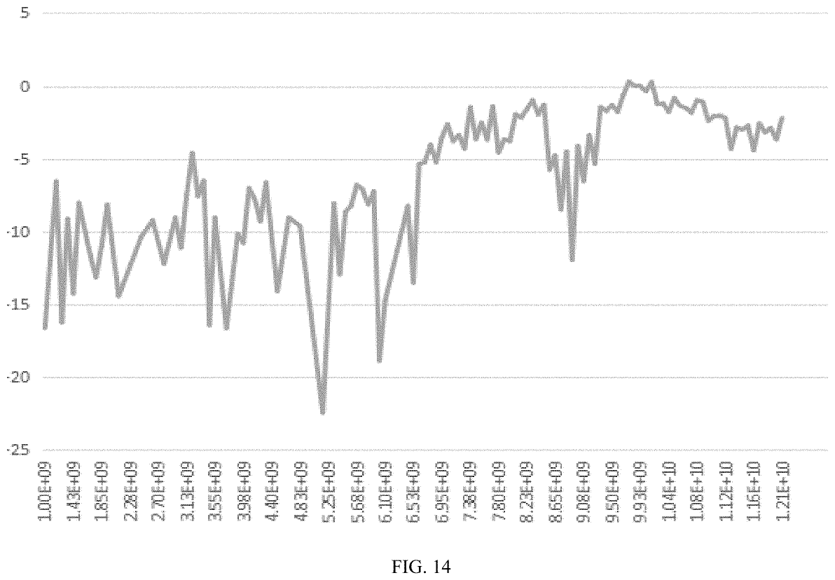

2. The anti-icing material with stealth function prepared in Example 2 was subjected to a reflectivity simulated test and a reflectivity actual test. The test results are shown in FIGS. 13 and 14. FIG. 13 shows a simulated test result of the reflectivity of the anti-icing material with stealth function obtained in Example 2, and FIG. 14 shows an actually measured result of the reflectivity of the anti-icing material with stealth function obtained in Example 2. It can be seen from FIGS. 13 and 14 that in low frequency wave band, a simulated test result of the reflectivity ranges from −10.2 dB to −10 dB, corresponding to a simulated reflectivity of 9%-10%, and an actually measured result of the reflectivity ranges from −13 dB to −8 dB, corresponding to an actually measured reflectivity of 5%-15%, indicating that the simulated test results are in consistent with the actually measured results.

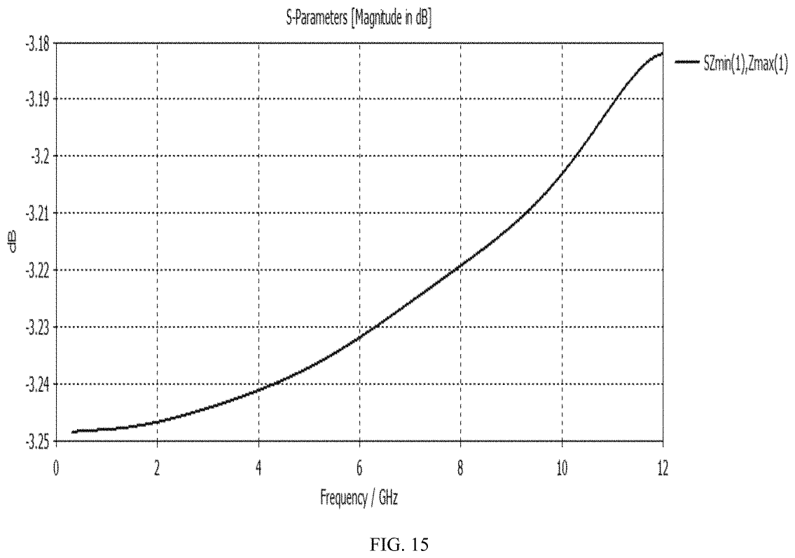

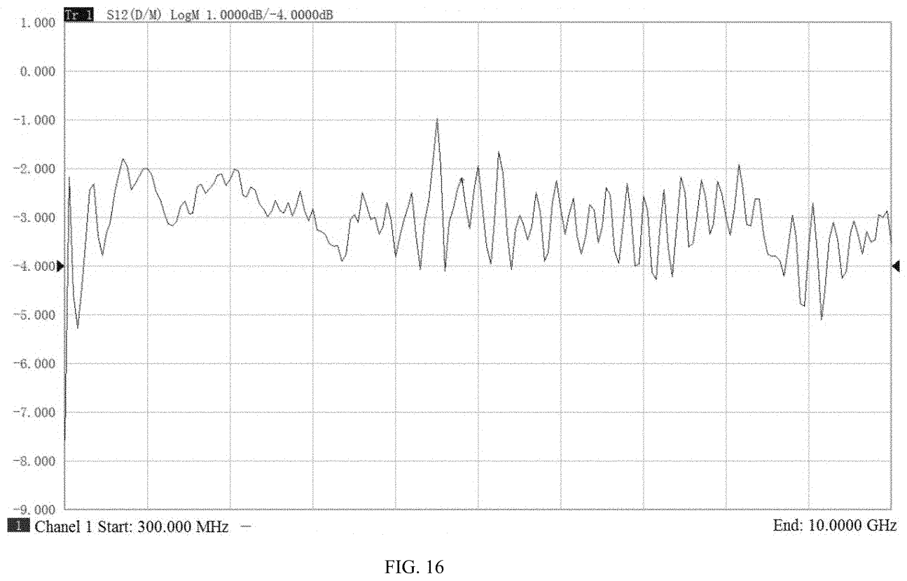

3. The anti-icing material with stealth function prepared in Example 2 was subjected to a transmissivity simulated test and a transmissivity actual test. The test results are shown in FIGS. 15 and 16. FIG. 15 shows the simulated test result of the transmissivity of the anti-icing material with stealth function obtained in Example 2, and FIG. 16 shows the actually measured result of the transmissivity of anti-icing material with stealth function obtained in Example 2. It can be seen from FIGS. 15 and 16 that a simulated test result of the transmissivity ranges from −3.2 dB to −3.1 dB, corresponding to a simulated transmissivity of 48%-49%, and an actually measured result of the transmissivity ranges from −3.7 dB to −2.1 dB, corresponding to an actually measured transmissivity of 43%-61%, indicating that the simulated test results are in consistent with the actually measured results.

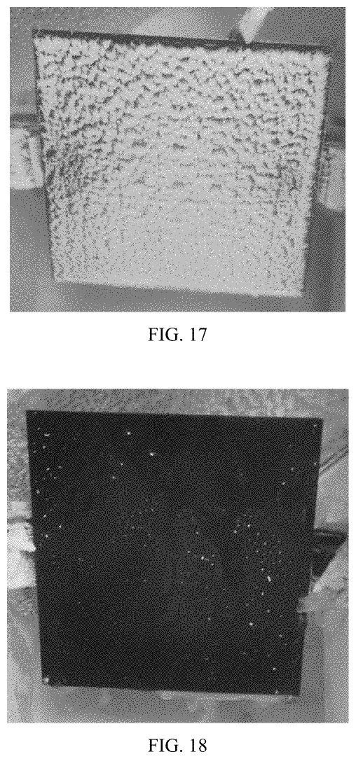

4. Anti-icing test: a sample with a size of 8 cm×8 cm was stood for 3-6 s at ambient temperature of 25° C., a wind tunnel condition (at a temperature of −47° C., a wind velocity of 10 m/s, and a liquid water content of 1.11 g/m³) was simulated, the surface appearances of the sample under non-heating condition and heating condition (at a given power density of 0.35 W/cm²) were respectively observed after being placed in the wind tunnel condition for 1.5 min. The surface appearance of the sample under non-heating condition is shown in FIG. 17, and the surface appearance of the sample under heating condition is shown in FIG. 18. It can be seen from FIGS. 17 and 18 that under the condition that the anti-icing material with stealth function according to the present disclosure is used and electrified, the anti-icing material with stealth function according to the present disclosure could effectively avoid ice attachment.

The above is only the preferred embodiments of the present disclosure. It should be pointed out that for those of ordinary skill in the art, without departing from the principle of the present disclosure, several improvements and modifications may be made, which should also be regarded as the scope of the present disclosure.

What is claimed is:

1. An anti-icing material with stealth function, comprising an electrically insulating and thermally insulating layer, a patterned heating layer, an electrically insulating and thermally conducting layer, and a hydrophobic layer that are disposed sequentially through stacking,
wherein the patterned heating layer has a patterned hollowed-out structure, and the patterned heating layer has a thickness of 20-400 μm.

2. The anti-icing material with stealth function of claim 1, wherein the electrically insulating and thermally insulating layer is made of a material comprising at least one selected from the group consisting of polyimide, glass fiber, hollow glassy microspheres, silicone rubber, and polyurethane, and the electrically insulating and thermally insulating layer has a thickness of 10-20 μm.

3. The anti-icing material with stealth function of claim 1, wherein the patterned heating layer comprises a polymer and a nano electrically conductive filler dispersed in the polymer, and a mass ratio of the polymer to the nano electrically conductive filler is in a range of (4-6):(1-2).

4. The anti-icing material with stealth function of claim 3, wherein the polymer comprises at least one selected from the group consisting of silicone rubber, epoxy resin, styrene-butadiene-styrene block copolymer, styrene butadiene rubber and polyurethane, and the nano electrically conductive filler comprises at least one selected from the group consisting of graphene, electrically conductive carbon black, carbon nanotubes, nano graphite powder, a nano metal powder, and a nano metal wire.

5. The anti-icing material with stealth function of claim 3, wherein the patterned hollowed-out structure of the patterned heating layer has a pattern that is at least one selected from the group consisting of a transversely and longitudinally symmetrical connectivity pattern, a pattern formed by removing a transversely and longitudinally symmetrical connectivity pattern from an bulk film, and a pattern formed by subjecting a transversely and longitudinally symmetrical connectivity pattern to a fractal processing,
wherein the pattern of the patterned hollowed-out structure is constructed of several pattern units, and the pattern units have a size of not larger than 100 mm.

6. The anti-icing material with stealth function of claim 5, wherein the patterned hollowed-out structure of the patterned heating layer is one of a one-layer structure and a multiple-layer structure,
wherein under the condition that the patterned hollowed-out structure is a multiple-layer structure, no additional material, a wave-absorbing material or a wave-transmitting material is added between layers of the patterned hollowed-out structure.

7. The anti-icing material with stealth function of claim 1, wherein the patterned hollowed-out structure of the patterned heating layer has a pattern that is at least one selected from the group consisting of a transversely and longitudinally symmetrical connectivity pattern, a pattern formed by removing a transversely and longitudinally symmetrical connectivity pattern from an bulk film, and a pattern formed by subjecting a transversely and longitudinally symmetrical connectivity pattern to a fractal processing,
wherein the pattern of the patterned hollowed-out structure is constructed of several pattern units, and the pattern units have a size of not larger than 100 mm.

8. The anti-icing material with stealth function of claim 1, wherein the patterned heating layer further comprises an electrode connected with the patterned heating layer at each end thereof.

9. The anti-icing material with stealth function of claim 1, wherein the electrically insulating and thermally conducting layer comprises a polymer matrix and a substance with high thermal conductivity and low electrical conductivity dispersed in the polymer matrix,
wherein the substance with high thermal conductivity and low electrical conductivity comprises at least one selected from the group consisting of a nitride with high thermal conductivity and low electrical conductivity, an oxide with high thermal conductivity and low electrical conductivity, and a thermally conductive silicone grease,
the polymer matrix comprises at least one selected from the group consisting of silicone rubber, epoxy resin, styrene-butadiene-styrene block copolymer, and polyurethane, and
the electrically insulating and thermally conducting layer has a thickness of not larger than 100 μm.

10. A method for preparing the anti-icing material with stealth function of claim 1, comprising
providing the electrically insulating and thermally insulating layer;
preparing the patterned heating layer on a surface of the electrically insulating and thermally insulating layer,
preparing the electrically insulating and thermally conducting layer on a surface of the patterned heating layer, and
preparing the hydrophobic layer on a surface of the electrically insulating and thermally conducting layer to obtain the anti-icing material with stealth function.

11. The method of claim 10, wherein the electrically insulating and thermally insulating layer is made of a material comprising at least one selected from the group consisting of polyimide, glass fiber, hollow glassy microspheres, silicone rubber, and polyurethane, and the electrically insulating and thermally insulating layer has a thickness of 10-20 μm.

12. The method of claim 10, wherein the patterned heating layer comprises a polymer and a nano electrically conductive filler dispersed in the polymer, and a mass ratio of the polymer to the nano electrically conductive filler is in a range of (4-6):(1-2).

13. The method of claim 12, wherein the polymer comprises at least one selected from the group consisting of silicone rubber, epoxy resin, styrene-butadiene-styrene block copolymer, styrene butadiene rubber and polyurethane, and the nano electrically conductive filler comprises at least one selected from the group consisting of graphene, electrically conductive carbon black, carbon nanotubes, nano graphite powder, a nano metal powder, and a nano metal wire.

14. The method of claim 12, wherein the patterned hollowed-out structure of the patterned heating layer has a pattern that is at least one selected from the group consisting of a transversely and longitudinally symmetrical connectivity pattern, a pattern formed by removing a transversely and longitudinally symmetrical connectivity pattern from an bulk film, and a pattern formed by subjecting a transversely and longitudinally symmetrical connectivity pattern to a fractal processing,
wherein the pattern of the patterned hollowed-out structure is constructed of several pattern units, and the pattern units have a size of not larger than 100 mm.

15. The method of claim 14, wherein the patterned hollowed-out structure of the patterned heating layer is one of a one-layer structure and a multiple-layer structure,
wherein under the condition that the patterned hollowed-out structure is a multiple-layer structure, no additional material, a wave-absorbing material or a wave-transmitting material is added between layers of the patterned hollowed-out structure.

16. The method of claim 10, wherein the patterned heating layer further comprises an electrode connected with the patterned heating layer at each end thereof.

17. The method of claim 10, wherein the electrically insulating and thermally conducting layer comprises a polymer matrix and a substance with high thermal conductivity and low electrical conductivity dispersed in the polymer matrix,
wherein the substance with high thermal conductivity and low electrical conductivity comprises at least one selected from the group consisting of a nitride with high thermal conductivity and low electrical conductivity, an oxide with high thermal conductivity and low electrical conductivity, and a thermally conductive silicone grease,
the polymer matrix comprises at least one selected from the group consisting of silicone rubber, epoxy resin, styrene-butadiene-styrene block copolymer, and polyurethane, and
the electrically insulating and thermally conducting layer has a thickness of not larger than 100 μm.

18. A method for using the anti-icing material with stealth function of claim 1, comprising applying the anti-icing material with stealth function onto a surface of equipment.

19. The method of claim 18, wherein the applying is performed by covering the surface of the equipment with the anti-icing material with stealth function.

20. The method of claim 18, wherein the applying is performed by sequentially preparing the electrically insulating and thermally insulating layer, the patterned heating layer, the electrically insulating and thermally conducting layer, and the hydrophobic layer on the surface of the equipment.
